(19) United States
(12) Patent Application Publication
(10) Pub. No.: US 2008/0043410 A1
(43) Pub. Date: Feb. 21, 2008

(54) Protective cover for multimedia players

(76) Inventor: Charles S. Yu, Jian-Gjun Township (TW)

Correspondence Address: Charles S. Yu, P.O. Box 6-9 (717), Tainan, omitted

(21) Appl. No.: 11/505,180

(22) Filed: Aug. 17, 2006

(51) Int. Cl. G06F 1/16; H05K 7/00

(52) U.S. Cl. 361/681

(57) ABSTRACT

A protective cover for multimedia players includes a cover body for receiving a multimedia player, and plural decorative figures adhered on an outer surface of the cover body. The cover body and the decorative figures are both made of flexible silica gel, preventing a multimedia player contained in the protective cover from being damaged or scarred by means of flexibility and enhancing its aesthetic value with various colors and various forms of the figures.

### BACKGROUND OF THE INVENTION

1. Field of the Invention

This invention relates to a protective cover for multimedia players, particularly to one composed of a protective cover made of flexible silica gel and plural decorative figures also made of flexible silica gel of different colors so as to enhance the aesthetic value of the cover.

2. Description of the Prior Art

A conventional protective cover for a multimedia players shown in FIG. 1 is generally single-colored with printed figures or characters, having inferior protective effect, So if a multimedia player with the conventional protective cover should fall down on the ground, the player might be damaged or scarred or its inner electronic circuit board might be broken.

### SUMMARY OF THE INVENTION

This invention has been devised to offer a kind of protective cover for multimedia players, which has a decorative figures made of flexible silica gel of varied colors adhered on the front surface of a multimedia player for preventing the player from damaged or scarred and for making the player more intriguing and increasing its aesthetic value.

### BRIEF DESCRIPTION OF DRAWINGS

This invention will be better understood by referring to the accompanying drawings, wherein:

FIG. 1 is a perspective view of a conventional protective cover for multimedia players;

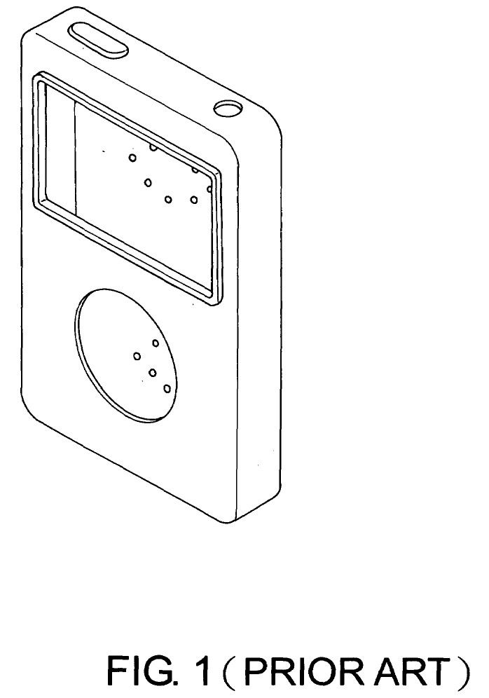

FIG. 2 is an exploded perspective view of first embodiment of a protective cover for multimedia players in the present invention;

FIG. 3 is a perspective view of the first embodiment of a protective cover for multimedia players in the present invention;

FIG. 4 is a perspective view of the first embodiment of a protective view for multimedia players practically housing a multimedia player in the present invention;

FIG. 5 is an exploded perspective view of a protective cover with decorative figures different from those used in FIGS. 2, 3 and 4 in the present invention.

### DETAILED DESCRIPTION OF THE PREFERRED EMBODIMENTS

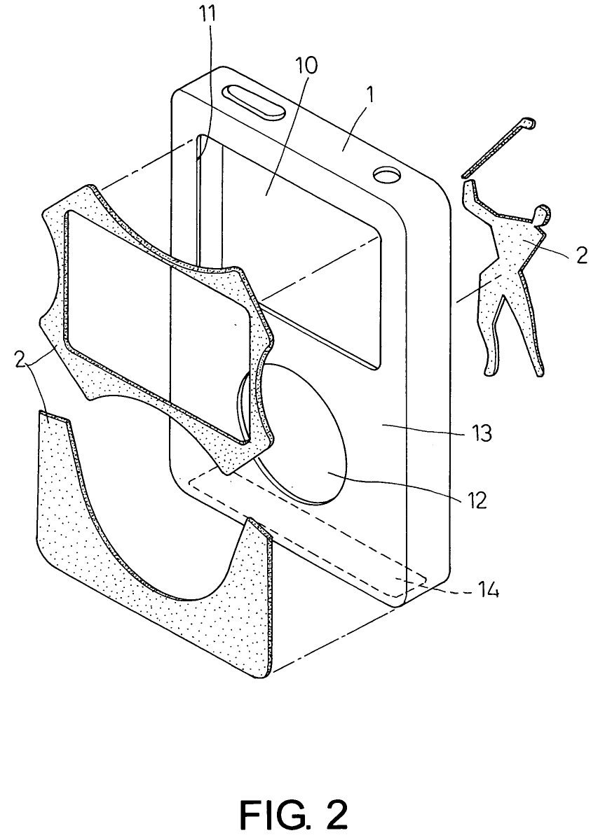

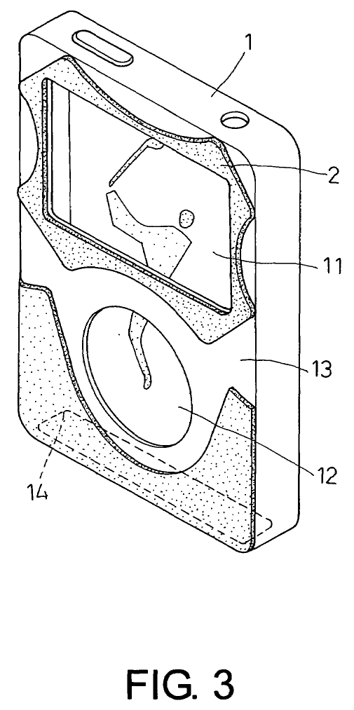

A preferred embodiment of a protective cover for multimedia players in the present invention, as shown in FIGS. 2 and 3, includes a cover body 1, and plural decorative figures 2 adhered on a front surface of the cover body 1. The cover body 1 and the decorative figures 2 are all made of flexible silica gel.

The cover body 1 is provided with an interior space 10, a screen hole 11 formed in an upper portion of the front wall, a button hole 12 formed in a lower portion of the front wall below the screen hole 11, a protective front surface 13, and a large hole 14 in the bottom.

The decorative figures 2 are adhered to be positioned on the front surface of the cover body 1 by means of two times of mechanical processes, having various colors different from that of the cover body 1. Then the whole protective cover may look multi-colored, having a better aesthetic value.

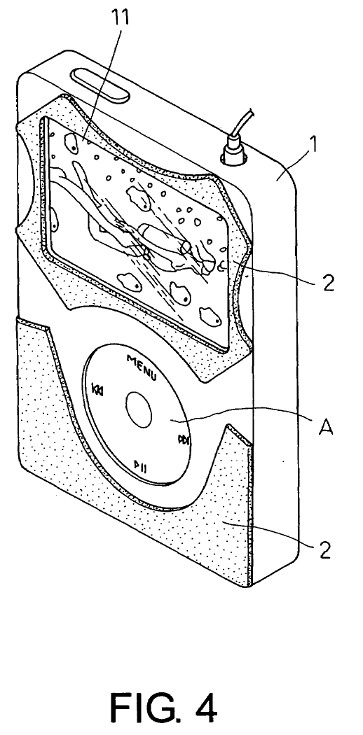

In using, a multimedia player (A) is inserted through the large opening 14 of the cover body 1 and positioned in the interior space 10, with the screen and the control button of the multimedia player (A) respectively seen through the screen hole 11 and the button hole 12, as shown in FIG. 4. Thus the multimedia player (A) is protected by the cover body 1, and further looks more beautiful by the decorative figures 2, enhancing the protectiveness and the appearance with the aesthetic value of the multimedia player (A).

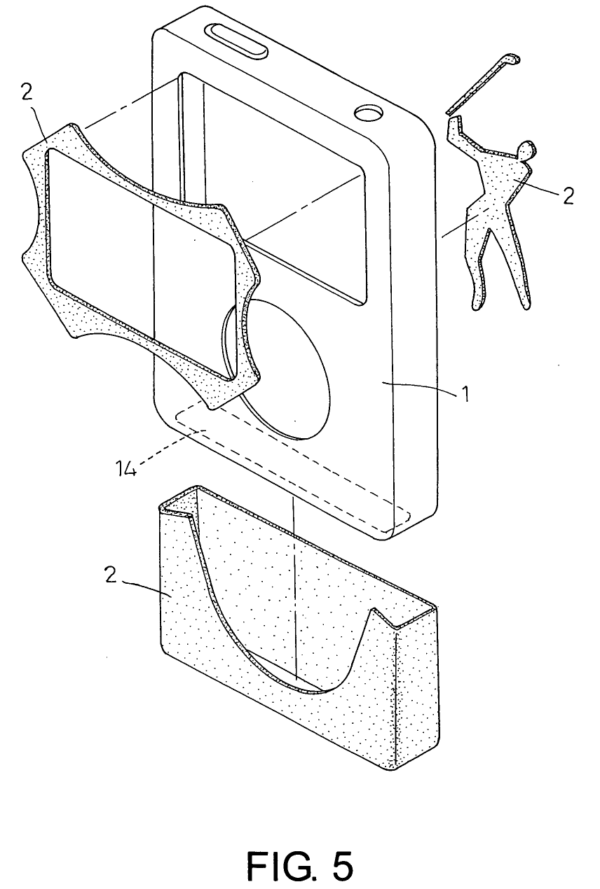

Next, FIG. 5 shows that the plural decorative figures 2 are made to have different shapes from those used in FIGS. 2, 3 and 4, varying the whole appearance of the protective cover to give different impression, with the cover body 1 shown in FIGS. 2, 3 and 4 having the same structure.

While the preferred embodiment of the invention has been described above, it will be recognized and understood that various modifications may be made therein and the appended claims may cover all such modifications that may fall within the spirit and scope of the invention.

What is claimed is:

1. A protective cover for multimedia players, said cover comprising:
a cover body made of flexible silica gel and provided with an interior space for receiving a multimedia player therein, a screen hole formed in an upper portion of an front wall for a screen of said multimedia player and a button hole formed in said front wall below said screen hole for a control button of said multimedia player and a protective front surface; and,
one or more than one decorative figures adhered on said protective front surface of said cover body and made of flexible silica gel of various colors and different patterns, said decorative figures enabling said protective cover look beautiful with various colors.
